(19) United States
(12) Patent Application Publication
(10) Pub. No.: US 2008/0003791 A1
(43) Pub. Date: Jan. 3, 2008

(54) Method for fabricating recess gate in semiconductor device

(75) Inventors: Yong-Tae Cho, Kyoungki-do (KR); Phil-Goo Kong, Kyoungki-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX Semiconductor Inc.

(21) Appl. No.: 11/644,884

(22) Filed: Dec. 26, 2006

(30) Foreign Application Priority Data
Jun. 30, 2006 (KR) 10-2006-0060327

(51) Int. Cl. H01L 21/4763

(52) U.S. Cl. 438/589; 257/E21.495

(57) ABSTRACT

A method for fabricating a recess gate in a semiconductor device includes etching a substrate to form a first recess, etching the substrate at side portions of the first recess to form a second recess, and forming a gate insulation layer and a gate electrode over the second recess, wherein etching the substrate to form the second recess includes performing an isotropic etching process.

### CROSS-REFERENCE TO RELATED APPLICATIONS

The present invention claims priority of Korean Patent Application Number 10-2006-0060327, filed on Jun. 30, 2006, which is incorporated by reference in its entirety.

### BACKGROUND OF THE INVENTION

The present invention relates to a method for fabricating a semiconductor device, and more particularly, to a method for fabricating a recess gate in a semiconductor device.

In a fabrication of a semiconductor device, a typical planar gate structure includes a gate formed over a plane active area. As the size of a pattern has decreased, a gate channel length has also decreased. Thus, an electric field has increased due to an increased ion doping concentration, causing junction leakage. Accordingly, it has become difficult to maintain a refresh characteristic of the device. In order to improve the difficulty, a three-dimensional recess gate structure has been introduced. Forming the three-dimensional recess gate structure includes forming a gate over a recess after recessing an active region. Such recess gate structure may allow increasing a channel length and decreasing an ion doping concentration. Thus, the refresh characteristic may be improved substantially.

FIG. 1 illustrates a cross-sectional view showing a typical recess gate structure. Device isolation structures 12 defining an active region are formed in a substrate 11. The active region of the substrate 11 is selectively etched to a certain thickness to form recesses 13. Recess gates RG are formed over the recesses 13. Each recess gate RG includes a gate insulation layer 14, a polysilicon layer 15 for use in a gate electrode, and a metal or metal silicide layer 16.

The above-described recess gate has advantages such as an increased gate channel length and a decreased ion implantation doping concentration, improving a refresh characteristic of the device. However, as devices have become highly integrated, a recess formed by a plasma etching process obtains a ‘V’ shape profile. Thus, silicon residues referred to as horns are generated between device isolation structures and an active region. Such horns cause characteristics of a subsequent gate insulation layer to deteriorate, and consequently, the horns become a stress point and functions as a leakage current source. Thus, production yield of the device may be reduced.

FIGS. 2A and 2B illustrate micrographic views showing limitations of the typical method. Referring to FIG. 2A, horns are formed between device isolation structures 12 and adjacent recesses 13 when an active region of a substrate is etched to form the recesses 13. Referring to FIG. 2B, a profile of trenches T has a slope formed in a manner that a width of the trenches T become smaller toward a bottom portion. As described earlier, recesses also have a profile that provides a width that narrows toward a bottom portion. Accordingly, horns may be generated. Such horns may cause deteriorated characteristics of a subsequent gate insulation layer and may become a stress point to function as a leakage current source.

### SUMMARY

Embodiments of the present invention are directed to provide a method for fabricating a recess gate in a semiconductor device, which can reduce deterioration of a gate insulation layer and generation of a leakage current source by reducing generation of horns in recess patterns.

In accordance with an aspect of the present invention, there is provided a method for fabricating a recess gate in a semiconductor device, including: etching a substrate to form a first recess; etching the substrate at side portions of the first recess to form a second recess; and forming a gate insulation layer and a gate electrode over the second recess.

### BRIEF DESCRIPTION OF THE DRAWINGS

FIG. 1 illustrates a cross-sectional view showing a typical recess gate.

FIGS. 2A and 2B illustrate micrographic views showing limitations of the typical method.

FIGS. 3A to 3D illustrate cross-sectional views showing a method for fabricating a recess gate in a semiconductor device according to an embodiment of the present invention.

FIG. 4 illustrates a cross-sectional view showing a result after a recess etching in accordance with the embodiment of the present invention.

FIGS. 5A and 5B illustrate micrographic views showing a device fabricated according to the embodiment of the present invention.

FIGS. 6A and 6B illustrate micrographic views to describe the embodiments of the present invention in detail.

FIGS. 7A to 7D illustrate graphs to describe the embodiments of the present invention in detail.

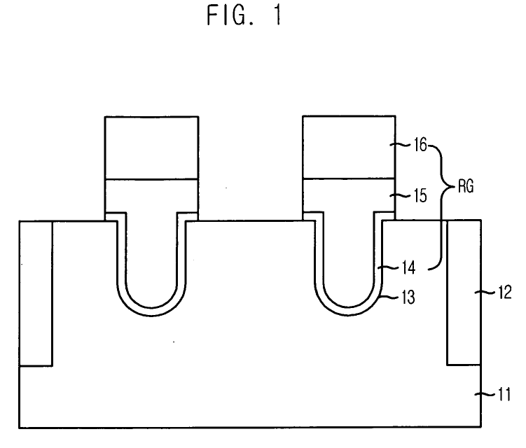

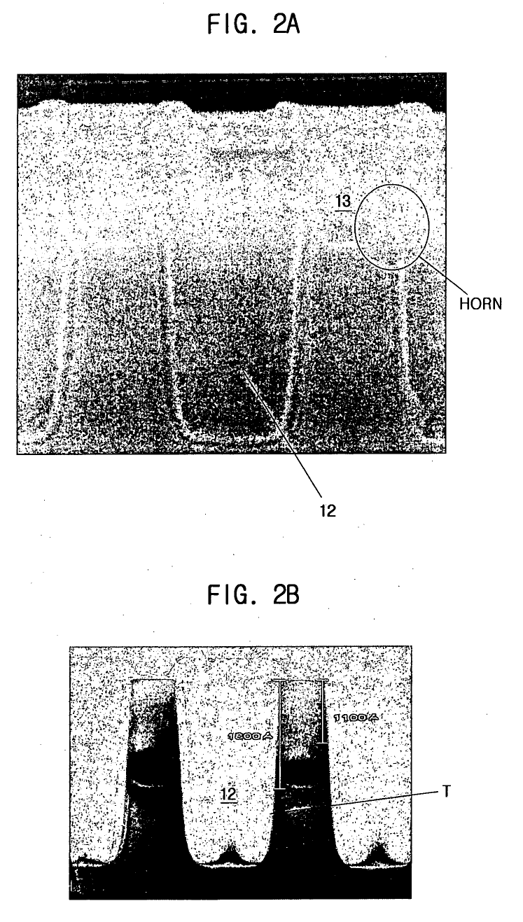

### DESCRIPTION

The present invention relates to a method for fabricating a recess gate in a semiconductor device. According to an embodiment of the present invention, a height of horns generated during a recess formation may be decreased, and thus, deterioration of a gate insulation layer characteristic and a leakage current source caused by concentrated stress may be removed. Also, it may be possible to obtain a benefit such as a reduced ion doping concentration according to an embodiment of the present invention, improving a refresh characteristic of the device. Thus, a design rule may be maintained and a process margin may be maximized. Furthermore, embodiments of this invention may provide advantages such as a large scale of integration of a semiconductor device including a logic, increased production yield, and reduced production costs.

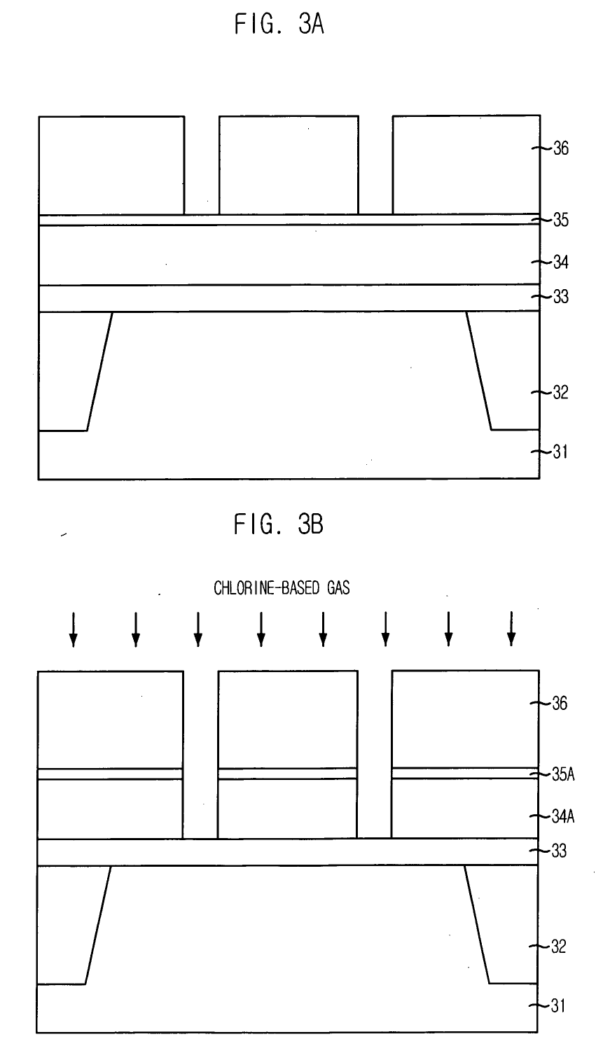

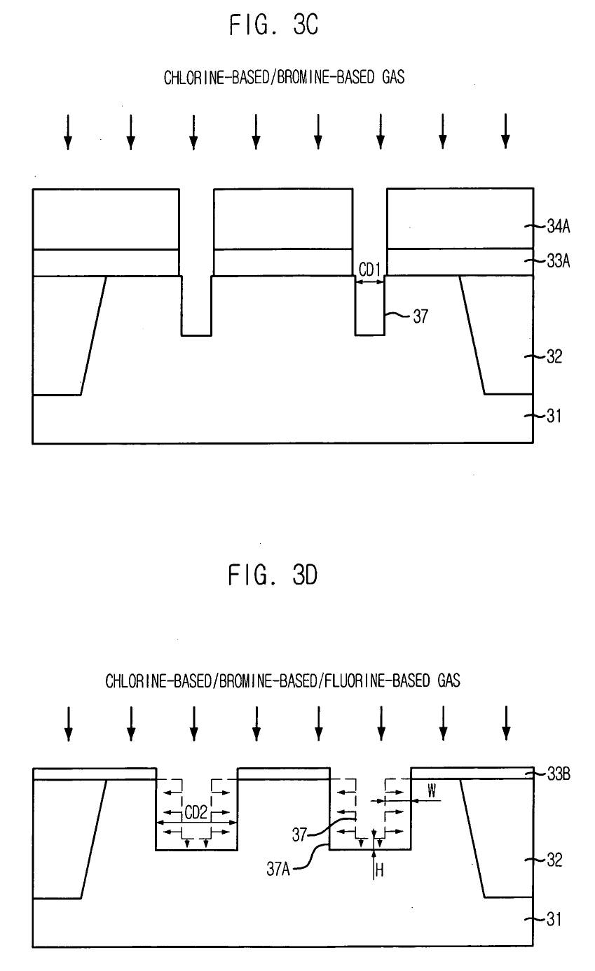

FIGS. 3A to 3D illustrate cross-sectional views showing a method for fabricating a recess gate in a semiconductor device according to an embodiment of the present invention.

Referring to FIG. 3A, device isolations 32 defining an active region and a field region are formed in a substrate 31. The device isolation structures 32 may be formed by employing a shallow trench isolation (STI) process. An oxide-based layer 33 for use as a hard mask and a polysilicon layer 34 for use as a hard mask are formed over the substrate 31. An organic bottom anti-reflective coating (BARC) layer 35 is formed over the polysilicon layer 34. A photoresist pattern 36 is formed over the BARC layer 35.

Referring to FIG. 3B, the BARC layer 35 and the polysilicon layer 34 are etched using the photoresist pattern 36 as an etch barrier to expose portions of the oxide-based layer 33. The etching of the polysilicon layer 34 includes implanting a chlorine-based plasma in a plasma source of a transformer coupled plasma (TCP) type or an inductivity coupled plasma (ICP) type, and supplying a source power and a bias power. Consequently, a polysilicon hard mask 34A is formed. Reference denotation 35A refers to a patterned BARC layer.

Referring to FIG. 3C, the photoresist pattern 36 is removed. The patterned BARC layer 35A is also removed. The oxide-based layer 33 and the substrate 31 are etched to form an oxide-based hard mask 33A and first recesses 37. A line width CD1 of the first recesses 37 is formed smaller than a line width of intended recesses by approximately 10 nm to approximately 15 nm.

The etching process for forming the first recesses 37 includes adding a bromine-based plasma to a chlorine-based plasma and supplying a source power and a bias power. In more detail, chlorine (Cl₂)/hydrogen bromide (HBr) plasma is used as a TCP type or an ICP type plasma source. A ratio of Cl₂ to HBr ranges approximately 1:5-20. The source power ranging from approximately 500 W to approximately 1,500 W and the bias power of approximately 500 W or less are supplied. The level of the bias power may be adjusted according to conditions of the process.

The first recesses 37 are formed by employing the etching process described above. The first recesses 37 may be formed using a pressure of approximately 25 mT, a radio frequency (RF) power of approximately 550 W, a bias power of approximately 350 W, and HBr flowing at a rate of approximately 100 sccm.

Referring to FIG. 3D, an isotropic etching process is performed to enlarge the line width CD1 of the first recesses 37, forming second recesses 37A. The second recesses 37A have an enlarged line width CD2. The polysilicon hard mask 34A may be removed during the etching processes for forming the first recesses 37 and the second recesses 37A.

The isotropic etching process includes performing the process under a pressure ranging from approximately 20 mT to approximately 100 mT, supplying a source power ranging from approximately 500 W to approximately 1,500 W and a bias power of approximately 50 W or less in a TCP type plasma source. The isotropic etching process uses an etch gas comprising a small amount of sulfur hexafluoride (SF₆)/oxygen (O₂) plasma and a large amount of Cl₂/HBr plasma. Although the bias power of approximately 0 W may be supplied, that is, not supplying the bias power, the bias power of approximately 50 W or less is supplied herein because the bias power may be required according to various etch apparatuses.

A ratio of SF₆ to O₂ to Cl₂ to HBr may be approximately 5:3:20:60 in the etch gas. The SF₆ gas of the SF₆/O₂ plasma functions to generate polymers. The Cl₂/HBr plasma is a reaction gas for etching silicon (Si). A fluorine-based gas, e.g., tetrafluoromethane (CF₄) or nitrogen trifluoride (NF₃), may be used to generate polymers instead of the SF₆ gas.

The isotropic etching process may be performed by supplying a source power ranging from approximately 300 W to approximately 2,000 W at an ICP type etch apparatus attached with a faraday shield using an etch gas including SF₆/O₂/Cl₂/HBr. The SF₆/O₂/Cl₂/HBr in the etch gas may have a ratio of approximately 5:3:20:60, respectively. Furthermore, the isotropic etching process may be performed at an etch apparatus using a plasma source of a microwave down stream (MDS) type, an electron cyclotron resonance (ECR) type, or a helical type.

The isotropic etching process etches substantially the same thickness in most directions due to characteristics of the isotropic etching process. In this embodiment of the present invention, the supply of the bias power is minimized to etch sidewall portions of the first recesses 37 more than bottom portions of the first recesses 37. Accordingly, a width difference W between the first recesses 37 and the second recesses 37A is larger than a height difference H between the first recesses 37 and the second recesses 37A.

The aforementioned isotropic etching process is performed to form the second recesses 37A having the line width CD2 enlarged by approximately 10 nm to approximately 15 nm when compared to the line width CD1 of the first recesses 37. The isotropic etching process may be performed under a pressure of approximately 20 mT, supplying a RF power of approximately 550 W and a bias power of approximately 350 W. The isotropic etching process may include flowing SF₆ at a rate of approximately 5 sccm, flowing O₂ at a rate of approximately 5 sccm, flowing Cl₂ at a rate of approximately 20 sccm, and flowing HBr at a rate of approximately 60 sccm. The oxide-based hard mask 33A may be partially etched during the isotropic etching process. The remaining oxide-based hard mask is denoted with reference denotation 33B. Although not illustrated, a gate insulation layer and a gate electrode are formed over the second recesses 37A after the remaining oxide-based hard mask 33B is removed. The gate electrode may have a stack structure including polysilicon and one of a metal layer and a metal silicide layer.

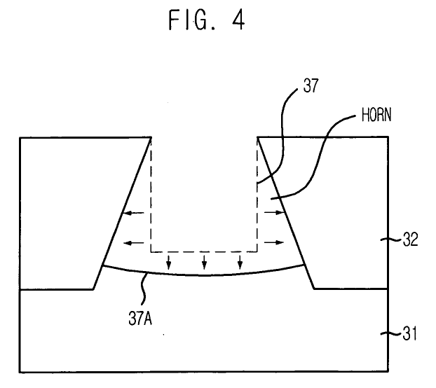

FIG. 4 illustrates a cross-sectional view showing a result after the recess etching process in accordance with the embodiment of the present invention. Horns formed between the device isolation structures 32 and the second recess 37A may be removed or partially removed such that chances of generating a deteriorated gate insulation characteristic and forming a stress point that functions as a leakage current source may be reduced. Thus, a production yield may not be decreased.

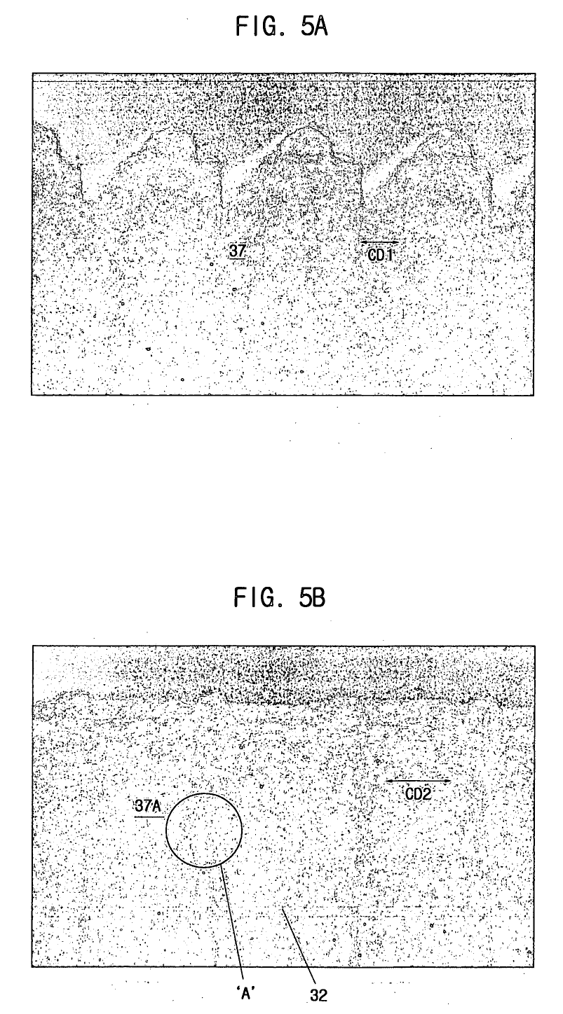

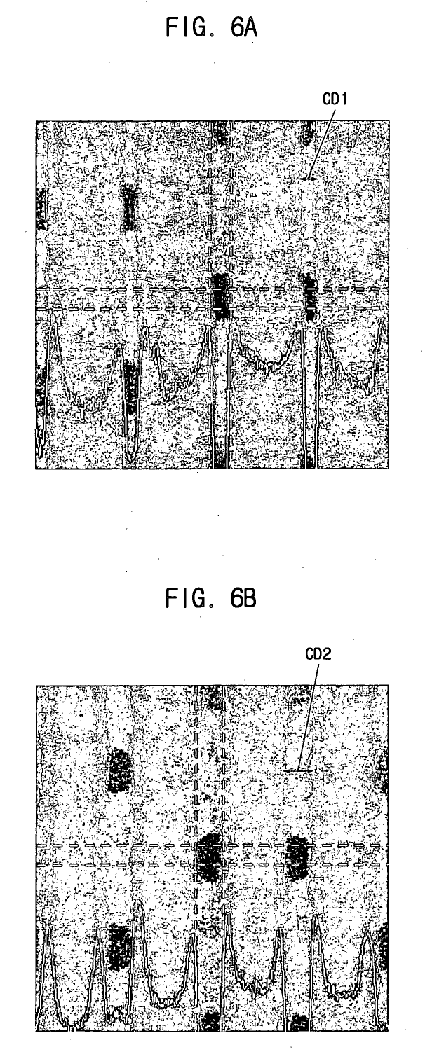

FIGS. 5A, 5B, 6A, and 6B illustrate micrographic views showing a recess pattern fabricated according to an embodiment of the present invention. Referring to FIGS. 5A and 6A, a substrate is etched using a polysilicon hard mask as an etch barrier to form first recesses 37 having a micro line width CD1. Referring to FIGS. 5B and 6B, an isotropic etching process is performed to form second recesses 37A having an enlarged line width CD2. Horns are reduced between the second recesses 37A and device isolation structures 32 (refer to ‘A’).

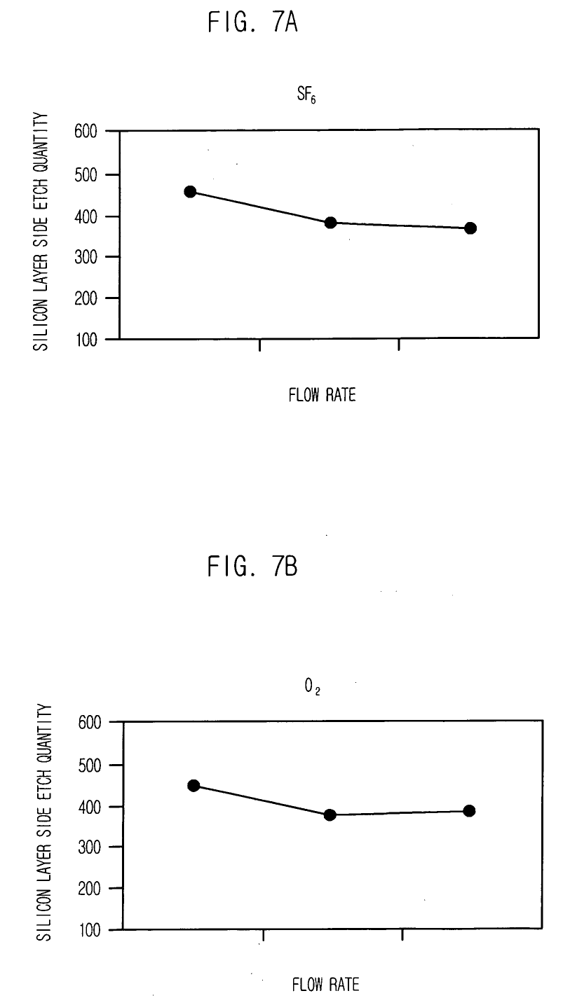

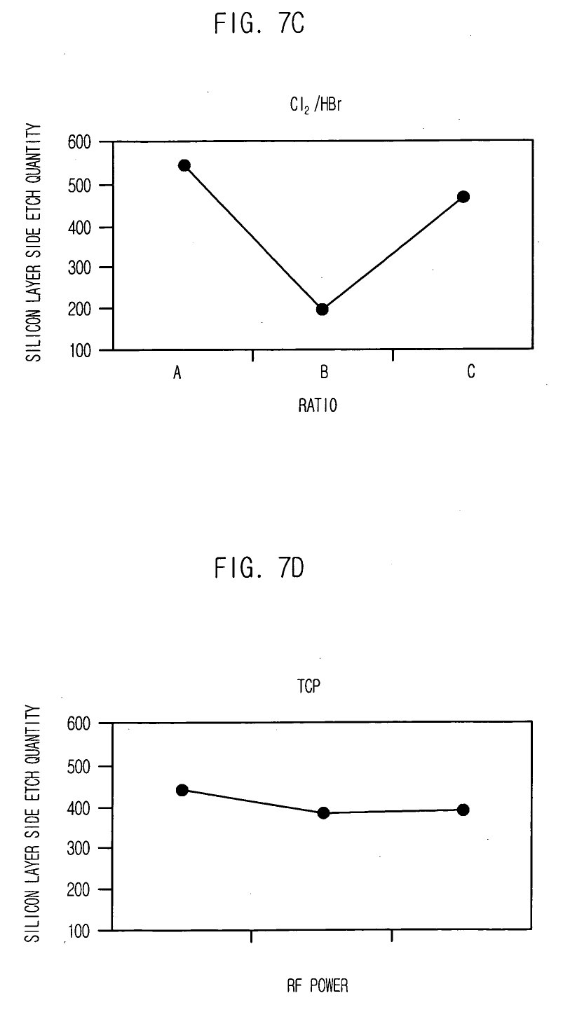

FIGS. 7A to 7D illustrate graphs to describe the embodiments of the present invention in detail. In particular, an embodiment of a T66 TIVA device is described. Side etch quantities of a silicon layer according to different gases are compared below.

Referring to FIG. 7A, a horizontal axis represents a flow rate of SF₆ plasma, and a vertical axis represents a side etch quantity of a silicon layer. As the flow rate of the SF₆ plasma increases, the side etch quantity of the silicon layer decreases.

Referring to FIG. 7B, a horizontal axis represents a flow rate ratio of O₂ plasma, and a vertical axis represents a side etch quantity of a silicon layer. As the flow rate of the O₂ plasma increases, the side etch quantity of the silicon layer decreases.

Referring to FIG. 7C, a horizontal axis represents a ratio between Cl₂ plasma and HBr plasma, and a vertical axis represents a side etch quantity of a silicon layer. A section A represents when the HBr plasma is implanted solely, a section B represents when the Cl₂ plasma is implanted solely, and a section C represents when the HBr plasma and the Cl₂ plasma are both implanted. The side etch quantity of the silicon layer is the largest when the HBr plasma is solely implanted, and is the smallest when the Cl₂ plasma is solely implanted. Implanting both of the HBr plasma and the Cl₂ plasma results in a medium value.

Referring to FIG. 7D, a horizontal axis represents a TCP RF power, and a vertical axis represents a side etch quantity of a silicon layer. As the TCP RF power increases, the side etch quantity of the silicon layer decreases. A degree of reduction is gentle, as depicted in FIG. 7D.

Referring to the FIGS. 7A to 7D, the side etch of the silicon layer is most actively performed when using the HBr/Cl₂ plasma with the RF power ranging approximately 400 W to approximately 500 W.

In accordance with the embodiments of the present invention, the deterioration of the gate insulation layer can be reduced by lessening or removing the horns formed between the device isolation structures and the recesses when forming the recess gates.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a recess gate in a semiconductor device, comprising:
etching a substrate to form a first recess;
etching sidewalls and a bottom of the first recess to form a second recess; and
forming a gate insulation layer and a gate electrode over the second recess.

2. The method of claim 1, wherein etching the sidewalls and the bottom of the first recess to form the second recess comprises performing an isotropic etching process.

3. The method of claim 2, wherein the isotropic etching process comprises using one of nitrogen trifluoride (NF₃) and sulfur hexafluoride (SF₆).

4. The method of claim 2, wherein the isotropic etching process comprises using an etch gas including a fluorine-based gas and a bromine-based gas.

5. The method of claim 2, wherein the isotropic etching process comprises using a gas mixture including an etch gas composed of a fluorine-based gas and a bromine-based gas, oxygen (O₂), and chlorine (Cl₂).

6. The method of claim 5, wherein the gas mixture comprises SF₆/O₂/Cl₂/hydrogen bromide (HBr).

7. The method of claim 6, wherein an amount of the SF₆/O₂ is smaller than an amount of the Cl₂/HBr in the gas mixture.

8. The method of claim 6, wherein a ratio of the SF₆ to the O₂ to the Cl₂ to the HBr in the gas mixture is approximately 5:3:20:60.

9. The method of claim 1, wherein etching the sidewalls and the bottom of the first recess to form the second recess comprises using a plasma etch apparatus.

10. The method of claim 9, wherein etching the sidewalls and the bottom of the first recess to form the second recess comprises using a pressure ranging from approximately 20 mT to approximately 100 mT, a source power ranging from approximately 500 W to approximately 1,500 W, and a bias power of approximately 50 W or less.

11. The method of claim 9, wherein etching the sidewalls and the bottom of the first recess to form the second recess comprises performing the etching at a transformer coupled plasma (TCP) type apparatus using a pressure ranging from approximately 20 mT to approximately 100 mT and a source power ranging from approximately 500 W to approximately 1,500 W, without supplying a bias power.

12. The method of claim 2, wherein the isotropic etching process comprises using a gas mixture including an etch gas composed of a carbon-based gas and HBr, O₂, and Cl₂.

13. The method of claim 12, wherein the carbon-based gas comprises tetrafluoromethane (CF₄).

14. The method of claim 1, wherein etching the sidewalls and the bottom of the first recess to form the second recess comprises performing the etching at an inductivity coupled plasma (ICP) type apparatus attached with a faraday shield using a power ranging from approximately 300 W to approximately 2,000 W.

15. The method of claim 14, wherein etching the sidewalls and the bottom of the first recess to form the second recess comprises using an etch gas including SF₆/O₂/Cl₂/HBr mixed at a ratio of approximately 5:3:20:60.

16. The method of claim 1, wherein etching the sidewalls and the bottom of the first recess to form the second recess comprises performing the etching at an etch apparatus using a plasma source selected from a group consisting of a microwave down stream (MDS) type, an electron cyclotron resonance (ECR) type, and a helical type.

17. The method of claim 1, wherein a line width of the second recess is larger than a line width of the first recess by approximately 10 nm to approximately 15 nm.

18. The method of claim 1, wherein etching a substrate to form the first recess comprises:
forming an oxide-based layer and a polysilicon layer over the substrate;
patterning the polysilicon layer; and
etching the oxide-based layer and the substrate using the patterned polysilicon layer.

19. The method of claim 18, wherein etching a substrate to form the first recess comprises using a plasma source of a TCP type or an ICP type, a mixed gas including Cl₂/HBr, and a power ranging from approximately 500 W to approximately 1,500 W.

20. The method of claim 19, wherein a ratio of the Cl₂ to the HBr in the mixed gas including Cl₂/HBr ranges approximately 1:5-20.
